(19) United States
(12) Patent Application Publication
(10) Pub. No.: US 2017/0243817 A1
(43) Pub. Date: Aug. 24, 2017

(54) SEMICONDUCTOR MEMORY DEVICE

(71) Applicant: Kabushiki Kaisha Toshiba, Minato-ku (JP)

(72) Inventor: Hiroki YAMASHITA, Yokkaichi (JP)

(73) Assignee: Kabushiki Kaisha Toshiba, Minato-ku (JP)

(21) Appl. No.: 15/211,602

(22) Filed: Jul. 15, 2016

Related U.S. Application Data
(60) Provisional application No. 62/297,292, filed on Feb. 19, 2016.

(51) Int. Cl. H01L 23/528; H01L 23/522; H01L 27/115

(52) U.S. Cl. CPC H01L 23/528; H01L 27/1157; H01L 27/11582; H01L 23/5226

(57) ABSTRACT

A semiconductor memory device includes a plurality of first electrode layers stacked; a second electrode layer provided on the first electrode layers; a third electrode layer arranged with the second electrode layers on the first electrode layers; a first insulating layer including a first layer provided between the second electrode layer and the third electrode layer, a second layer provided between the second electrode layer and the first layer, and a third layer provided between the third electrode layer and the first layer; a plurality of semiconductor layers extending through the first electrode layers in a stacked direction thereof, and disposed in an arrayed arrangement; and a charge storage portion positioned between one of the first electrode layers and one of the semiconductor layers.

### CROSS-REFERENCE TO RELATED APPLICATIONS

This application is based upon and claims the benefit of priority from U.S. Provisional Patent Application 62/297,292 filed on Feb. 19, 2016; the entire contents of which are incorporated herein by reference.

### FIELD

Embodiments are generally related to a semiconductor memory device.

### BACKGROUND

A non-volatile semiconductor memory device is under developing, which includes three-dimensionally disposed memory cells. For example, a NAND-type semiconductor memory device comprises a memory cell array that includes a plurality of control electrodes and a semiconductor channel extending through the plurality of electrodes. It may be necessary for such a semiconductor memory device to improve the breakdown voltage between the control electrodes in order to have the memory cells of higher density.

### BRIEF DESCRIPTION OF THE DRAWINGS

FIG. 1 is a perspective view schematically showing a semiconductor memory device according to an embodiment;

FIGS. 2A and 2B are schematic views showing a part of the semiconductor memory device according to the embodiment;

FIGS. 3A to 31 are schematic views showing a manufacturing process of the semiconductor memory device according to the embodiment;

FIGS. 4A to 4C are schematic views showing a part of the semiconductor device according to the embodiment;

FIGS. 5A to 5C are schematic views showing a part of a semiconductor memory device according to a comparative example;

FIGS. 6A to 6D are schematic cross-sectional views showing a part of a semiconductor memory device according to a first variation of the embodiment;

FIGS. 7A to 7D are schematic cross-sectional views showing a part of a semiconductor memory device according to a second variation of the embodiment; and

FIGS. 8A to 8D are schematic cross-sectional views showing a part of a semiconductor memory device according to a third variation of the embodiment.

### DETAILED DESCRIPTION

According to one embodiment, a semiconductor memory device includes a plurality of first electrode layers stacked; a second electrode layer provided on the first electrode layers; a third electrode layer arranged with the second electrode layers on the first electrode layers; a first insulating layer including a first layer provided between the second electrode layer and the third electrode layer, a second layer provided between the second electrode layer and the first layer, and a third layer provided between the third electrode layer and the first layer; a plurality of semiconductor layers extending through the first electrode layers in a stacked direction thereof, and disposed in an arrayed arrangement; and a charge storage portion positioned between one of the first electrode layers and one of the semiconductor layers.

Embodiments will now be described with reference to the drawings. The same portions inside the drawings are marked with the same numerals; a detailed description is omitted as appropriate; and the different portions are described. The drawings are schematic or conceptual; and the relationships between the thicknesses and widths of portions, the proportions of sizes between portions, etc., are not necessarily the same as the actual values thereof. The dimensions and/or the proportions may be illustrated differently between the drawings, even in the case where the same portion is illustrated.

There are cases where the dispositions of the components are described using the directions of XYZ axes shown in the drawings. The X-axis, the Y-axis, and the Z-axis are orthogonal to each other. Hereinbelow, the directions of the X-axis, the Y-axis, and the Z-axis are described as an X-direction, a Y-direction, and a Z-direction. Also, there are cases where the Z-direction is described as upward and the direction opposite to the Z-direction is described as downward.

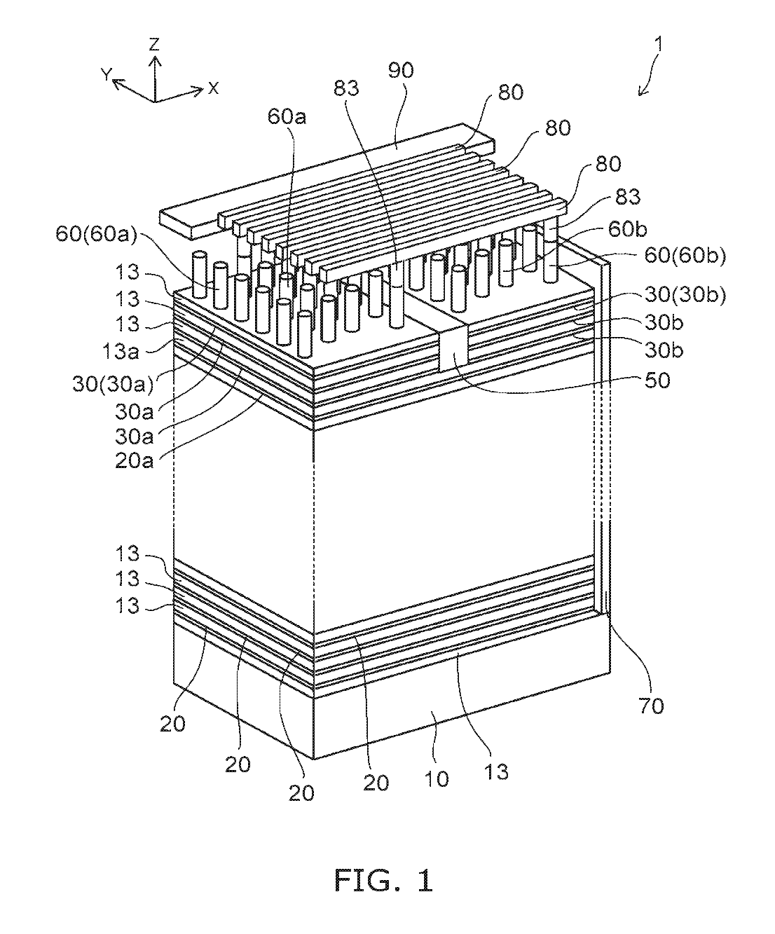

FIG. 1 is a perspective view showing a semiconductor memory device 1 according to an embodiment. The semiconductor memory device 1 is, for example, a NAND-type non-volatile memory device, and includes the three dimensionally disposed memory cells.

As shown in FIG. 1, the semiconductor memory device 1 includes a conductive layer (hereinafter, a source layer 10), a plurality of first electrode layers stacked (hereinafter, word lines 20), a second electrode layer (hereinafter, a selection gate 30a) and a third electrode layer (hereinafter, a selection gate 30b). The selection gates 30a and 30b are disposed side by side on the word lines 20 that are stacked on the source layer 10.

The source layer 10 is, for example, a P-type well provided in a silicon substrate (not shown). The source layer 10 may be a poly-crystalline silicon layer provided via an inter-layer insulating layer (not shown) on a silicon substrate (not shown). The word lines 20, the selection gates 30a and 30b are, for example, metal layers that include tungsten (W).

Each of the word lines 20 has planar broadening, and stacked on a surface of the source layer 10. Hereinafter, the stacked direction of the word lines 20 is defined as a first direction, for example, referred to as the Z-direction. An insulating layer 13 is provided between the word lines adjacent to each other in the Z-direction. The insulating layer 13 is, for example, a silicon oxide layer.

The selection gates 30a and 30b is, for example, arranged in the X-direction on the word lines 20. The selection gates 30a and 30b each include a plurality of stacked layers disposed on the word lines 20 as shown in the figure. The insulating layer 13 is also provided respectively between the uppermost layer 20a of the word lines 20 and the selection gate 30a, between the uppermost layer 20a and the selection gate 30b, and between the stacked layers adjacent to each other in the Z-direction of the selection gate 30a and 30b. Hereinafter, the stacked layers are referred respectively to as a selection gate 30a or 30b.

The semiconductor memory device 1 further includes a first insulating layer (hereinafter, an insulating layer 50) and a plurality of semiconductor layers 60. The insulating layer 50 is provided between the selection gates 30a and 30b, and extends in the Y-direction. The plurality of semiconductor layers 60 extend in the Z-direction through the word lines 20. The plurality of semiconductor layers 60 are electrically connected at bottom ends thereof to the source layer 10.

The plurality of semiconductors 60 includes, for example, a plurality of first semiconductor layers (hereinafter, semiconductor layers 60a) and a plurality of second semiconductor layers (herein after, semiconductor layers 60b). The semiconductor layers 60a extend respectively in the Z-direction through the selection gates 30a. The semiconductor layers 60b extend respectively in the Z-direction through the selection gates 30b.

Hereinafter, the selection gates 30a and 30b are described as selection gates 30 except for the case where it is necessary to distinguish between the selection gates 30a and 30b. The semiconductor layers 60a and 60b are also described as semiconductor layers 60 in the same manner.

The semiconductor memory device 1 further includes, for example, a plurality of first interconnections (hereinafter, bit lines 80) and a second interconnection (hereinafter, source line 90) provided above the selection gates 30. One of the semiconductor layers 60a and one of the semiconductor layers 60b are electrically connected to and share one of the bit lines 80. The semiconductor layers 60 each are electrically connected the bit line 80 through a contact plug 83. The source line 90 is electrically connected to the source layer 10 through a source contact body 70. As shown in FIG. 1, the source contact body 70 extends in the Y-direction and the Z-direction along each lateral surface of word lines 20 and selection gates 30.

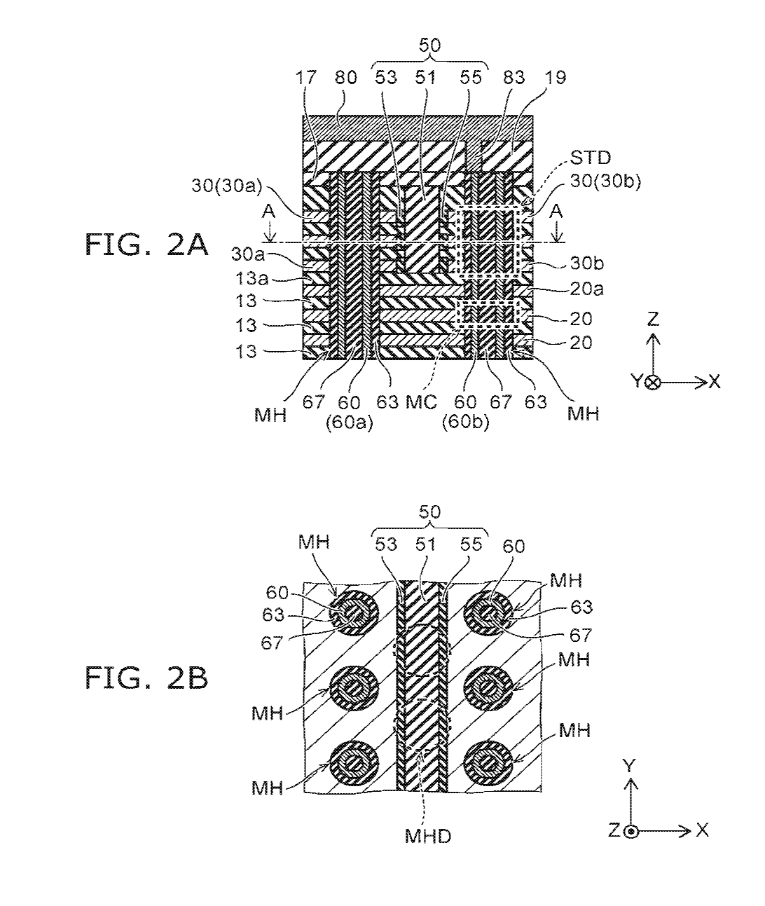

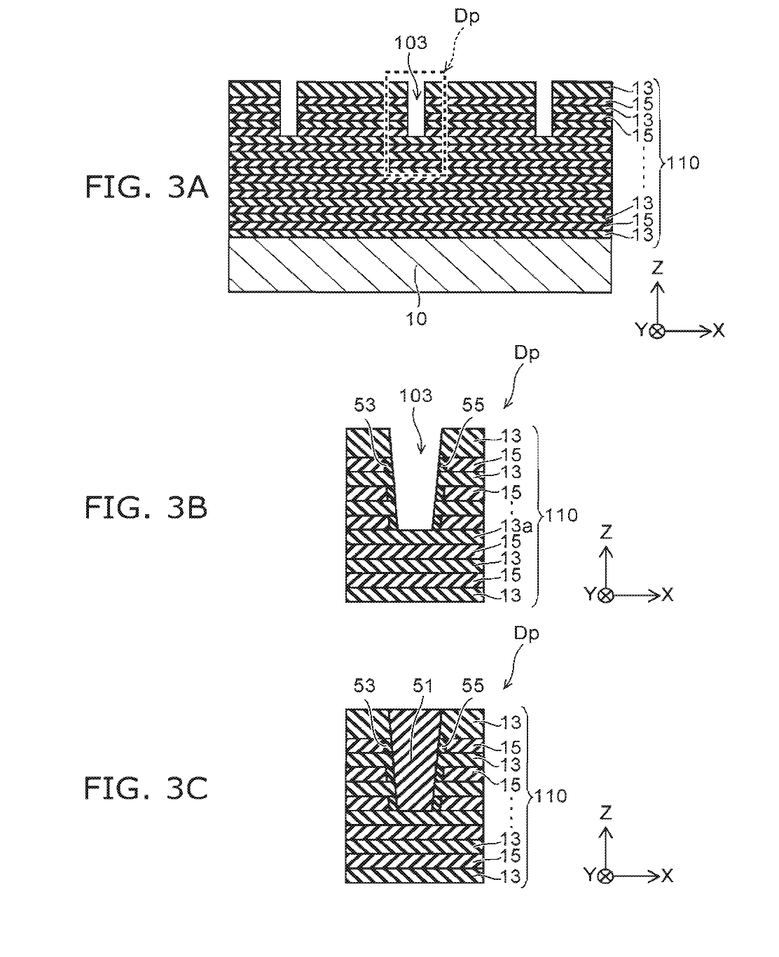

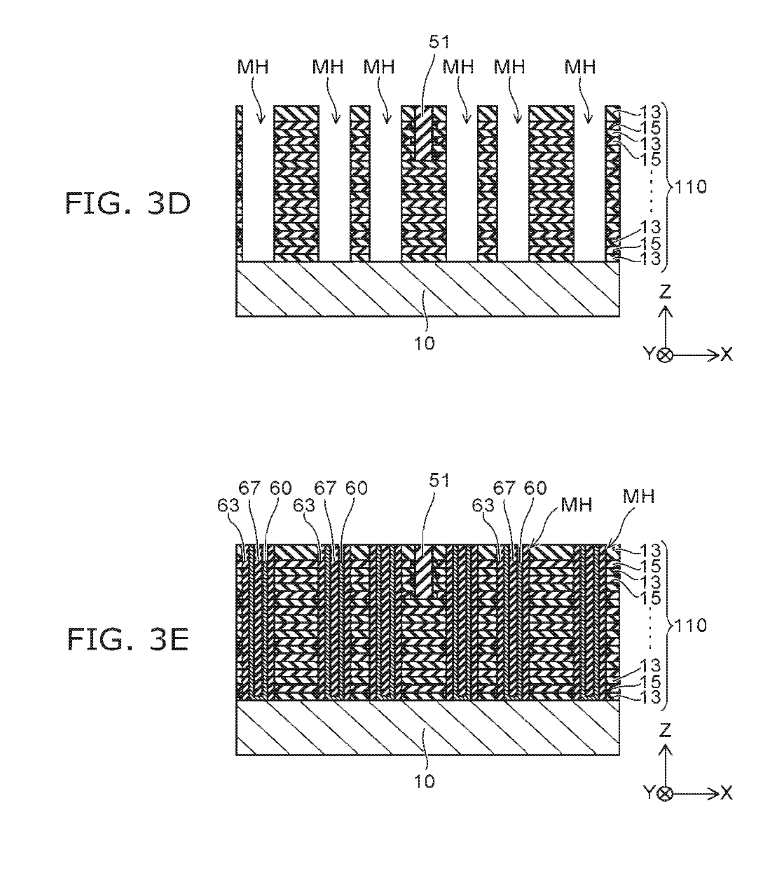

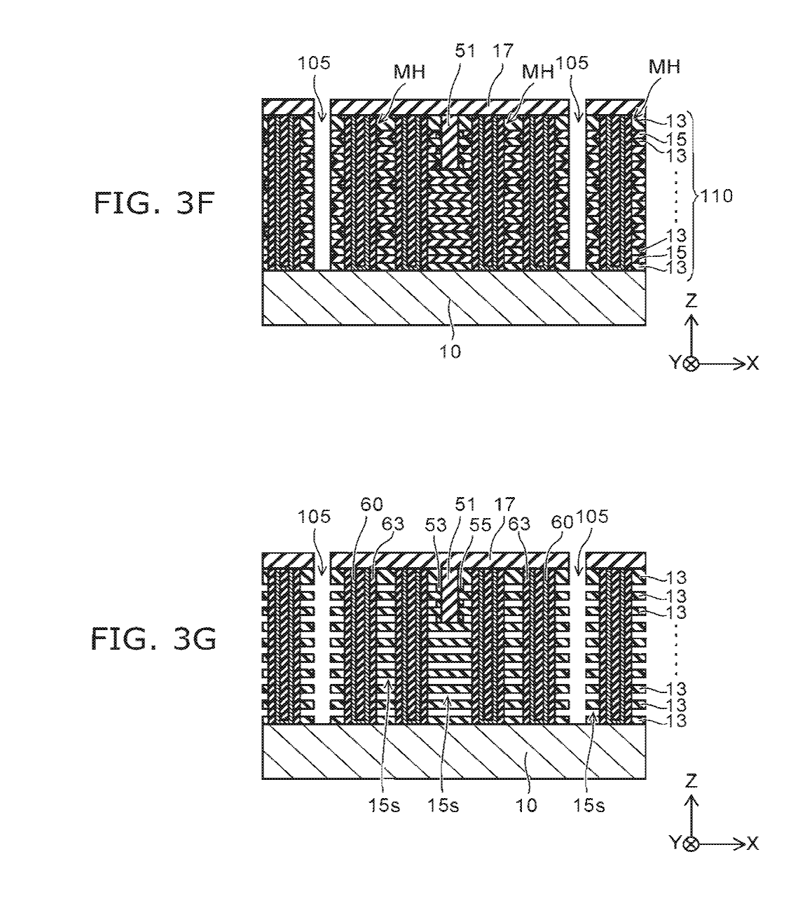

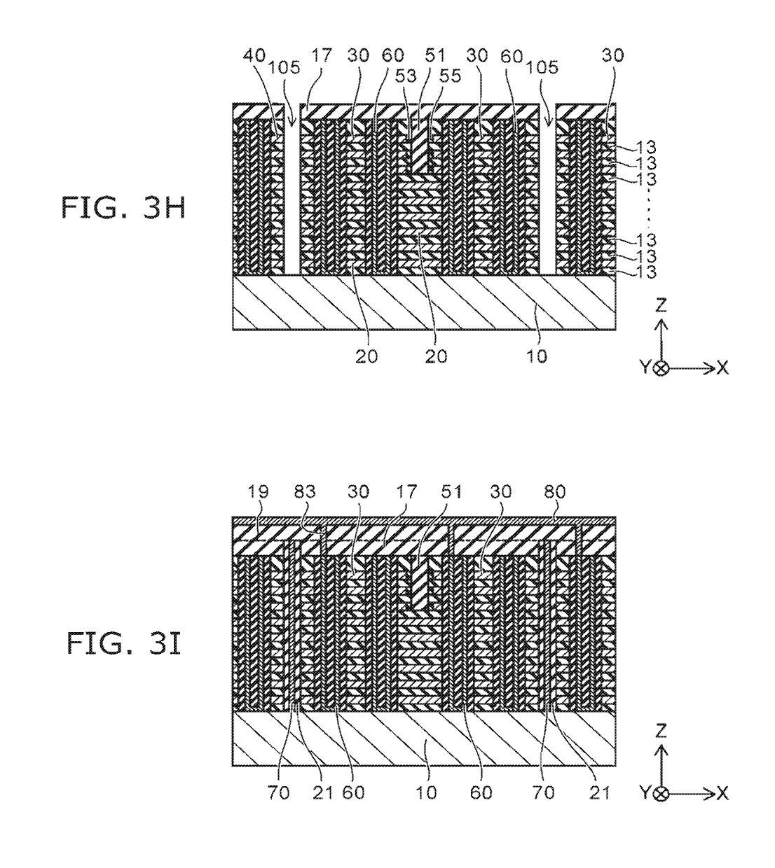

It should be noted in FIG. 1 that an insulating layer 19 provided between the selection gate 30 and the bit line 80 (see FIG. 2A) and an insulating layer 21 provided between the source contact body 70 and each of the word lines 20 and the selection gate 30 (see FIG. 3I) are omitted for showing a structure of the semiconductor memory device 1.

FIGS. 2A and 2B are schematic views showing a part of the semiconductor memory device 1 according to the embodiment. FIG. 2A is the schematic view showing a part of cross-section taken along the X-Z plane. FIG. 2B is the schematic view showing a cross-section taken along A-A line shown in FIG. 2A. Hereinafter, the structure of the semiconductor memory device 1 is precisely described with reference to FIGS. 2A and 2B.

The semiconductor memory device 1 includes memory holes MH extending in the Z-direction through the word lines 20 and the selection gate 30. The memory holes MH each include a semiconductor layer 60, an insulating layer 63 and a core body 67. The insulating layer 63 is provided between an inner wall of a memory hole MH and the semiconductor layer 60, and extends along the semiconductor layer 60. The semiconductor layer 60 is positioned between the insulating layer 63 and the core body 67. The core body 67 is provided so as to fill the inside of the memory hole MH.

The semiconductor layer 60 is provided in the memory hole MH extending through the selection gate 30. Memory cells MC are provided at portions where the semiconductor layer 60 extends through the word lines 20. The semiconductor layer 60 acts as a channel of each memory cell MC; and the word lines act as control gates of the memory cells.

The insulating layer 63 has, for example, an ONO structure, wherein a silicon oxide, a silicon nitride and a silicon oxide are stacked on the inner wall of the memory hole MH. The insulating layer 63 includes a portion positioned between a word line 20 and the semiconductor layer 60, which acts as a charge storage portion of a memory cell MC.

A selection transistor STD is provided at a portion where the semiconductor layer 60 extends through the selection gate 30. The semiconductor layer 60 acts as a channel of the selection transistor STD; and the selection gate 30 acts as a gate electrode of the selection transistor STD. A part of the insulating layer 63 positioned between the selection gate 30 and the semiconductor layer 60 acts as a gate insulating film.

As described above, the semiconductor memory device 1 comprises a plurality of NAND strings each including a plurality of memory cells MC and a selection transistor STD disposed along a semiconductor layer 60. For example, increasing the density of memory cells MC by reducing the distance between the memory holes MH may be advantageous for enlarging the memory capacity of the semiconductor memory device. There may be a case, however, where the current leakage becomes larger due to lowering the breakdown voltage between the selection gates 30a and 30b, when a space between the selection gates 30a and 30b becomes narrow in order to increase the density of memory holes MH.

In the embodiment, the insulating layer 50 is provided between the selection gates 30a and 30b. The insulating layer 50 includes, for example, a first layer 51, a second layer 53 and a third layer 55. The second layer 53 is provided between the selection gate 30a and the first layer 51. The third layer 55 is provided between the selection gate 30b and the first layer 51. The first layer 51 is, for example, a silicon nitride layer. The second layer 53 and the third layer 55 are, for example, silicon oxide layers. Alternatively, the second layer 53 and the third layer 55 may be oxynitride layers.

The insulating layer 50 includes, for example, an interface between insulating layers different in the layer quality from each other on the current leakage pathway from the selection gate 30a to the selection gate 30b. Such an interface traps, for example, the charges moving from the selection gate 30a to the selection gate 30b, and thus, makes the potential barrier between the insulating layers become higher. Thereby, it is possible to suppress the current leakage flowing between the selection gates 30a and 30b by improving the breakdown voltage of the insulating layer 50.

As shown in FIG. 2A, the semiconductor memory device 1 includes, for example, the selection gates 30a and 30b that are provided on the uppermost layer 20a of the word lines 20. The semiconductor memory device 1 further includes a second insulating layer (hereinafter, an insulating layer 13a) which is provided between the uppermost layer 20a and the selection gate 30a, and between the uppermost layer 20a and the selection gate 30b. The first layer 51 extends between a plurality of selection gates 30a and a plurality of selection gates 30b; and the bottom end of the insulating layer 51 is, for example, in contact with the insulating layer 13a. Alternatively, the bottom end of the insulating layer 50 may be provided so as to divide the insulating layer 13a.

FIG. 2B is the schematic view showing an example of the arrangement of the memory holes MH provided in the semiconductor memory device 1. For example, a memory hole MHD may be provided in addition to the memory holes MH extending through the selection gates 30 so as to divide the insulating layer 50 along the Y-direction. That is, it is preferable to maintain the periodicity of memory holes MH by providing the memory hole MHD, when reducing the distance between the memory holes MH, and thus, lacking the periodicity thereof at the position where the insulating layer 50 is provided. Thereby, it is possible, for example, in the step for forming the memory holes MH to improve the uniformity of hole patterns provided in a resist layer using photolithography.

There may be a case, however, where the structural defects are induced by an unexpected shape of the memory hole MHD when the insulating layer 50 has less resistivity against the etching for forming the memory hole MHD as described later. Thus, in the embodiment, the first layer 51 is made of material that has high resistivity against the etching for forming the memory holes MH, thereby suppressing the occurrence of structural defects, and improving the manufacturing yield.

Hereinafter, a manufacturing method of the semiconductor memory device is described with reference to FIGS. 3A to 31. FIGS. 3A to 31 are schematic views showing a manufacturing process of the semiconductor memory device according to the embodiment.

As shown in FIG. 3A, a stacked body 110 is formed by alternately stacked insulating layers 13 and 15 on the source layer 10. The insulating layers 13 are, for example, silicon oxide layers. The insulating layers 15 are, for example, silicon nitride layers. The insulating layers 13 and 15 are formed, for example, using chemical vapor deposition (CVD).

Then, a groove 103 is formed, which extends downward from the top surface of the stacked body 110. The groove 103 is formed to divide at least one of the insulating layers 15 and to expose the insulating layer 13a at the bottom thereof (see FIG. 3B). In this example, the groove 103 is formed to divide three insulating layers 15. The groove 103 is formed, for example, using reactive ion etching (RIE), and extends in the Y-direction.

FIGS. 3B and 3C are the schematic cross-sectional views showing a divided portion Dp shown in FIG. 3A. As shown in FIG. 3B, the end portions of the insulating layers 15 exposed in the wall surfaces of the groove 103 are converted to the first layer 53 and the second layer 55.

For example, the second layer 53 and the third layer 55 are formed by thermally oxidizing the insulating layers 15 exposed in the wall surfaces of the groove 103. The second layer 53 and the third layer 55 are, for example, silicon oxide layers or silicon oxynitride layers. The second layers 53 and the third layers 55 are formed, for example, so as to have a thickness of not less than 3 nanometers (nm) in the X-direction.

As shown in FIG. 3C, the first layer 51 is formed in the groove 103. The first layer 51 is, for example, a silicon nitride layer. For example, a silicon nitride layer is formed using CVD so as to fill the groove 103 and cover the top surface of the stacked body. Then, the first layer 51 is formed by etching back the silicon nitride layer, leaving a portion that fills the groove 103.

As shown in FIG. 3D, memory holes MH are formed from the top surface of the stacked body 110 so as to have a depth capable of reaching the source layer 10. The memory holes MH are formed, for example, by selectively removing the insulating layers 13 and 15 using anisotropic RIE. The source layer 10 is exposed at the bottom surfaces of the memory holes MH.

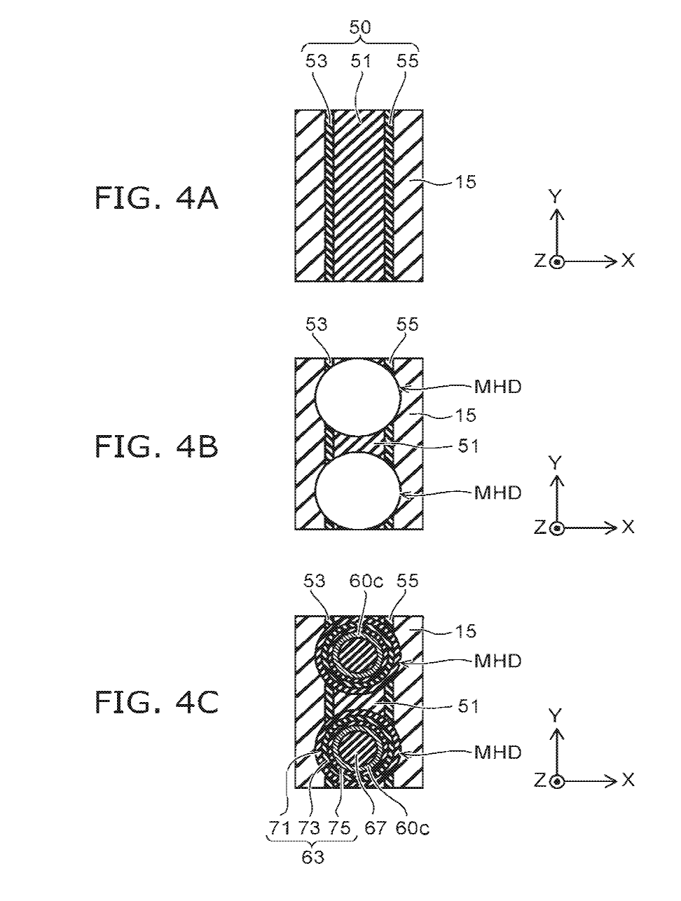

As shown in FIG. 3E, an insulating layer 63, a semiconductor layer 60 and a core body 67 are formed in each of memory holes MH. The insulating layer 63 is formed, for example, using CVD so as to have a structure in which a silicon oxide layer, a silicon nitride layer and a silicon oxide layer are stacked in order on the inner wall of the memory hole MH (see FIG. 4C). The semiconductor layer 60 is, for example, a poly-crystallized silicon layer formed using CVD, and covers the insulating layer 63 and the source layer 10 exposed at the bottom surface of the memory hole MH. The core body 67 is, for example, a silicon oxide formed using CVD, and is embedded in the memory hole MH.

As shown in FIG. 3F, an insulating layer 17 is formed to cover the top surface of the stacked body 110. The insulating layer 17 is, for example, a silicon oxide layer formed using CVD. Then, a slit 105 is formed from the top surface of the insulating layer 17 so as to have a depth capable of reaching the source 10. The slit 105 is formed, for example, using anisotropic RIE, and extends in the Y-direction and the Z-direction. The slit 105 divides the stacked body 110 into a plurality of portions each including the insulating layer 50 and a plurality of memory holes MH.

As shown in FIG. 3G, the insulating layers 15 are selectively removed by etching liquid supplied through the slit 105. For example, it is possible to selectively remove the insulating layers 15 by supplying hot phosphoric acid as the etching liquid, when the insulating layers 13 are silicon oxide layers, and the insulating layers 15 are silicon nitride layers. During this process, the second layer 53 and the third layer 55 has a resistivity against the etching liquid, and protect the first layer 51.

As shown in FIG. 3H, word lines 20 and selection gates 30 are formed in the spaces 15s from which the insulating layers 15 are removed (see FIG. 3G). The word lines 20 and the selection gates 30 include, for example, tungsten layers formed using CVD. The word lines 20 and the selection gates 30 may include barrier metal such as titanium nitride (TiN) formed between a tungsten layer and an insulating layer 13.

The second layer 53 and the third layer 55 each have a thickness not less than 3 nanometers in the X-direction. Thus, the first layer 51 is provided with a distance of 3 nanometers from each selection gate 30.

As shown in FIG. 3I, a source contact body 70 is formed in the slit 105. The source contact body 70 is, for example, a tungsten layer, and is electrically connected to the source layer. The source contact body 70 is electrically insulated from the word lines 20 and the selection gates 30 by an insulating layer 21. The insulating layer 21 is, for example, a silicon oxide layer formed using CVD.

Then, an insulating layer 19 is formed to cover the insulating layer 17 and the source contact body 70. Further, the bit lines 80 and the source line 90 (see FIG. 1) are formed on the insulating layer 19. The bit lines 80 are electrically connected to semiconductor layers 60 through contact plugs 83. The source contact body 70 is electrically connected to the source line 90 at a portion not shown.

FIGS. 4A to 4C are schematic views showing a part of the semiconductor memory device 1 according to the embodiment. FIGS. 4A to 4C is the schematic views showing the partial cross-sectional views taken along A-A line shown in FIG. 2A, and showing an example of forming the memory holes MHD.

The memory holes MHD is formed, for example, at the same time with the memory holes MH at the step showing in FIG. 3D. As shown in FIGS. 4A and 4B, the memory holes MHD is formed, for example, so as to divide the insulating layer 50 in the Y-direction. Further, as shown in FIG. 4C, a semiconductor layer 60c, an insulating layer 63 and a core body 67 are also provided in each memory hole MHD. In other words, the semiconductor layer 60c (the third semiconductor layer) divides the insulating layer 50.

The insulating layer 63 includes, for example, a first layer 71, a second layer 73 and a third layer 75. The first layer 71 is, for example, a silicon oxide layer, and covers the inner wall of the memory hole MHD. The second layer 73 is, for example, a silicon nitride layer, and is formed between the first layer 71 and the third layer 75. The third layer 75 is, for example, a silicon oxide layer, and is formed between the second layer 73 and the semiconductor layer 60c.

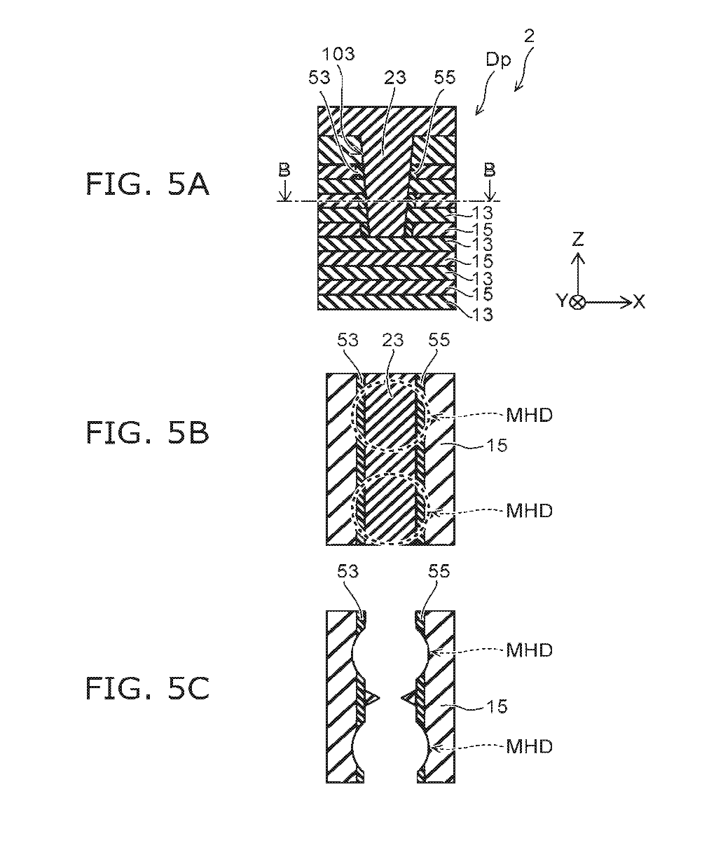

FIGS. 5A to 5C are schematic views showing a part of a semiconductor memory device 2 according to a comparable example. FIG. 5A is the schematic cross-sectional view showing the part corresponding to the divided portion Dp shown in FIG. 3A. FIGS. 5B and 5C is the schematic views showing the cross-section taken along the B-B line shown in FIG. 5A.

In the example shown in FIG. 5A, the groove 103 is filled with an insulating layer 23. When the insulating layer 23 has, for example, inferior resistivity against the RIE used for forming the memory holes MHD comparing with the second layer 53 and the third layer 55, the memory holes MHD cannot keep the prescribed shape, and as shown in FIG. 5C, are formed so as to extend in the Y-direction and the reverse direction thereof (the −Y direction). Such a phenomenon may occur, for example, in the case where a silicon oxide layer formed using CVD is used as the insulating layer 23. That is, the insulating layer 23 has inferior resistivity against the RIE comparing with the second layer 53 and the third layer 55 formed by the thermally oxidization and the insulating layer 15 that is the silicon nitride layer.

There may be a case where the memory holes MHD extended in the Y-direction as shown in FIG. 5C induces a structural defect, for example, in the process of forming the semiconductor layer 60, the insulating layer 63 and the core body 67 (see FIG. 3E), and serves as a factor that lowers the manufacturing yield.

In contrast, in the embodiment, the silicon nitride layer 15 is used, for example, as the first insulating layer 15 shown in FIG. 4A. Thus, it is possible to keep the shape of memory holes MHD as shown in FIG. 4B. That is, the shape change of the memory holes MHD is suppressed by using material that has superior resistivity against the RIE for the first layer 51, thereby improving the manufacturing yield.

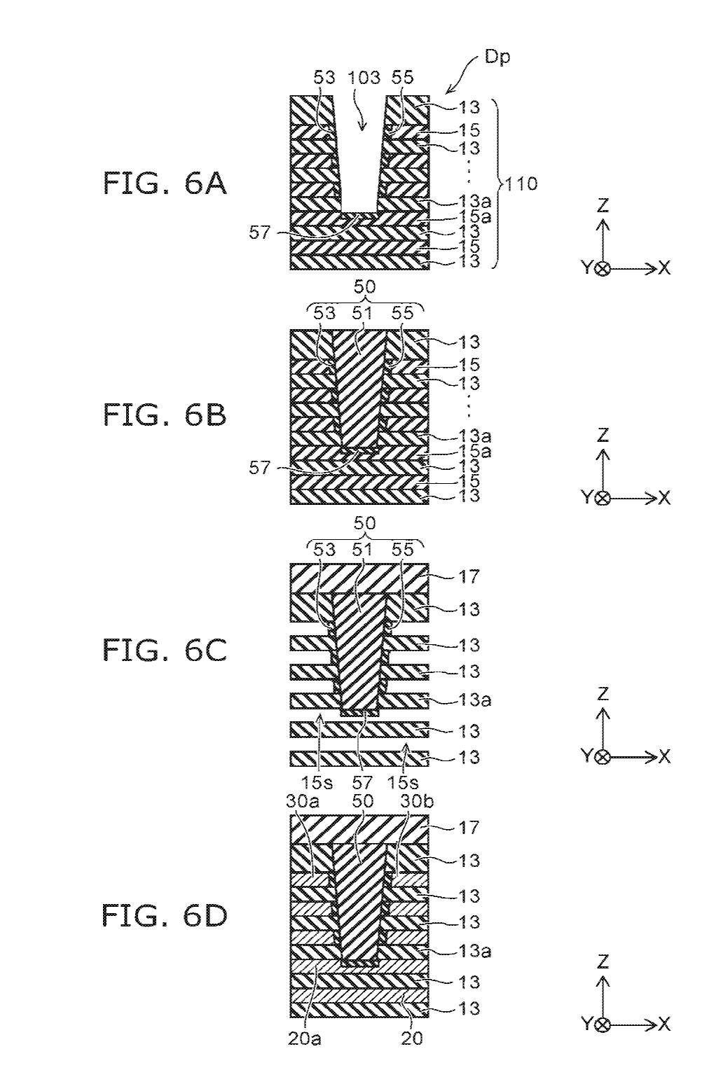

FIGS. 6A to 6D is schematic cross-sectional views showing a part of a semiconductor memory device 1 according to a first variation of the embodiment. FIGS. 6A to 6D are the schematic views showing the divided portion Dp shown in FIG. 3A.

In the example shown in FIG. 6A, a groove 113 is formed from the top surface of the stacked body 110 so as to extend through the insulating layers 13, 15 and 13a to reach an insulating layer 15a. The insulating layer 15a is exposed at the bottom surface of the groove 113. Further, a forth layer 57 is formed by oxidizing the insulating layer 15a exposed at the bottom surface of the groove 113 through the process in which the second layer 53 and the third layer 55 are formed by thermally oxidizing the insulating layers 15 exposed in the wall surface of the groove 113. The fourth insulating layer 57 is, for example, a silicon oxide layer or a silicon oxynitride layer.

As shown in FIG. 6B, the first layer 51 is formed in the groove 113. The first layer 51 is, for example, a silicon nitride layer.

As shown in FIG. 6C, the insulating layers 15 are selectively removed. The insulating layer 15a is removed, leaving the forth layer 57. The fourth layer 57 protects the first layer 51 through the etching process of the insulating layers 15.

As shown in FIG. 6D, the word lines 20 and the selection gates 30 are formed in the spaces 15s from which the insulating layers are removed. The topmost layer 20a of the word lines 20 is also formed after the removal of the insulating layers 15a.

In this example, the insulating layers 15 are surely separated, which are provided at higher levels than a level of the insulating layer 13a, by forming the groove 113 so as to extend through the insulating layer 13a. Thereby, it is possible to improve the electrical isolation between the selection gates 30a and 30b.

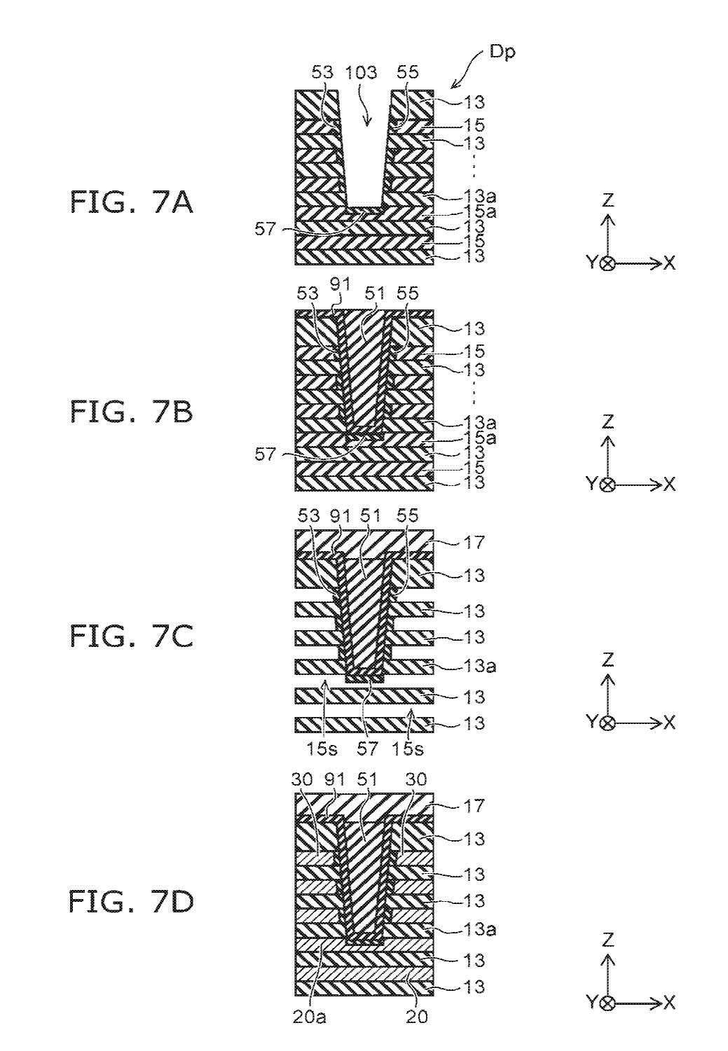

FIGS. 7A to 7D are schematic views showing a part of a semiconductor memory device 1 according to a second variation of the embodiment. FIGS. 7A to 7D are the schematic views showing the cross-section of the divided portion Dp shown in FIG. 3A.

As shown in FIG. 7A, the groove 113 is formed from the top surface of the stacked body 110 so as to extend through the insulating layers 13, 15 and 13a to reach the insulating layer 15a. Further, the second layer 53, the third layer 55 and the fourth layer 57 are formed by thermally oxidizing the insulating layers 15 exposed in the wall surface of the groove 113 and the insulating layer 15a exposed at the bottom surface of the groove 113.

As shown in FIG. 7B, an insulating layer 91 is formed to cover the inner surface of the groove 113, and further, the first layer 51 is formed in the groove 113. The insulating layer 91 is, for example, a silicon oxide layer.

As shown in FIG. 7C, the insulating layers 15 are selectively removed. In this example, the first layer 51 is surely protected through the etching process of the insulating layers 15 by providing the insulating layer 91.

As shown in FIG. 7D, the word lines 20 and the selection gates 30 and 40 are formed in the spaces 15s from which the insulating layers 15 are removed.

In this example, the resistivity of protection layers (the second layer 53, the third layer 55 and the insulating layer 91) is improved against the etching through the process in which the insulating layers 15 are selectively removed. Thereby, the unintended change of the hole shape is suppressed by the first layer 51 through the step of forming the memory holes MHD.

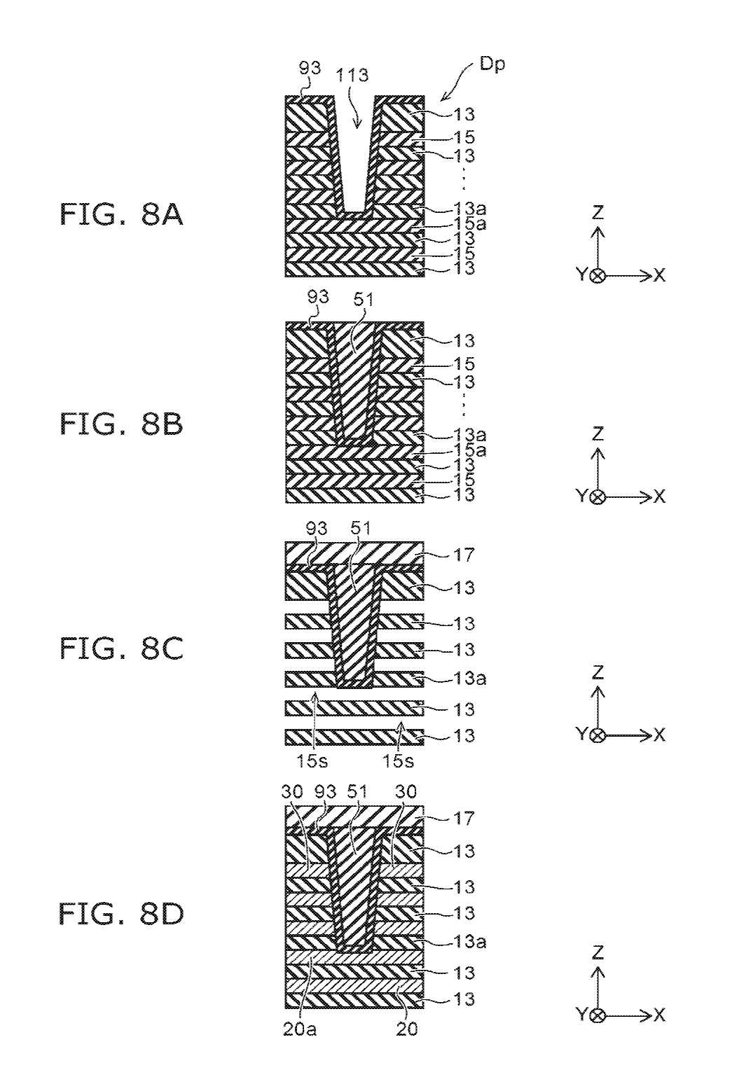

FIGS. 8A to 8D are schematic cross-sectional views showing a part of a semiconductor memory device 1 according to a third variation of the embodiment. FIGS. 8A to 8D are the schematic views showing a cross-section of the divided portion Dp shown in FIG. 3A.

As shown in FIG. 8A, the groove 113 is formed from the top surface of the stacked body 110 so as to extend through the insulating layers 13, 15 and 13a to reach the insulating layer 15a. Further, an insulating layer 93 is formed to cover the inner surface of the groove 113. The insulating layer 93 is, for example, a silicon oxide layer. Alternatively, the insulating layer 93 may have, for example, the ONO structure in which a silicon oxide layer, a silicon nitride layer and another silicon oxide layer are stacked in order.

As shown in FIG. 8B, the first layer 51 is formed in the groove 113. Further, the insulating layers 15 are selectively removed as shown in FIG. 8C. In this example, the first layer 51 is protected by the insulating layer 93 through the etching process of the insulating layers 15.

As shown in FIG. 8D, the word lines 20 and selection gates 30 are formed in the spaces 15s from which the insulating layers 15 are removed. In this example, a part of the insulating layer 93 acts as the second layer between the selection gate 30a and the first layer 51. Another part of the insulating layer 93 acts as the third layer between the selection gate 30b and the first layer 51.

That is, the insulating layer 93 protects the first layer 51 through the process of the selective removal of the insulating layers 15. Thus, the unintended change of the hole shape is suppressed by the first layer 51 through the process of forming the memory holes MHD.

While certain embodiments have been described, these embodiments have been presented by way of example only, and are not intended to limit the scope of the inventions. Indeed, the novel embodiments described herein may be embodied in a variety of other forms; furthermore, various omissions, substitutions and changes in the form of the embodiments described herein may be made without departing from the spirit of the inventions. The accompanying claims and their equivalents are intended to cover such forms or modifications as would fall within the scope and spirit of the invention.

1: A semiconductor memory device comprising:
a plurality of first electrode layers stacked in a first direction;
a second electrode layer provided on the first electrode layers;
a third electrode layer arranged with the second electrode layer on the first electrode layers;
a first insulating layer including a first layer provided in a groove between the second electrode layer and the third electrode layer, a second layer provided between the second electrode layer and the first layer, and a third layer provided between the third electrode layer and the first layer,
a plurality of semiconductor layers extending through the first electrode layers in the first direction, and disposed in an arrayed arrangement; and
a charge storage portion positioned between one of the first electrode layers and one of the semiconductor layers, wherein
the semiconductor layers include a first semiconductor layer extending through the second electrode layer, a second semiconductor layer extending through the third electrode layer, and a third semiconductor layer dividing the first layer of the first insulating layer.

2: The semiconductor memory device according to claim 1, wherein
the first layer is provided away from the second electrode layer and the third electrode layer respectively with a distance not less than 3 nanometers.

3: The semiconductor memory device according to claim 1, further comprising:
a second insulating layer provided on the uppermost layer of the plurality of first electrode layers, the second insulating layer extending between the uppermost layer and the second electrode layer, and between the uppermost layer and the third electrode layer, wherein
the first layer has a bottom end contacting the second insulating layer.

4: The semiconductor memory device according to claim 1, further comprising:
a second insulating layer provided on the uppermost layer of the plurality of first electrode layers, the second insulating layer extending between the uppermost layer and the second electrode layer, and between the uppermost layer and the third electrode layer, wherein
the first layer divides the second insulating layer.

5: The semiconductor memory device according to claim 1, further comprising:
a second insulating layer provided on the uppermost layer of the plurality of first electrode layers, the second insulating layer extending between the uppermost layer and the second electrode layer, and between the uppermost layer and the third electrode layer, wherein
the first insulating layer further includes a fourth layer positioned between the first layer and the uppermost layer.

6-7. (canceled)

8: The semiconductor memory device according to claim 1, further comprising:
a third insulating layer extending in the first direction along the third semiconductor layer, wherein
the third insulating layer positioned between the third semiconductor layer and the first layer of the first insulating layer.

9: The semiconductor memory device according to claim 1, further comprising:
another second electrode layer stacked on the second electrode layer; and
another third electrode layer stacked on the third electrode layer, wherein
the first insulating layer is positioned between the another second electrode layer and the another third electrode layer,
the first semiconductor layer extends through the another second electrode layer, and the second semiconductor layer extends through the another third electrode layer.

10: The semiconductor memory device according to claim 1, wherein
the first layer includes silicon nitride, and
the second layer and the third layer include silicon oxide.

11: The semiconductor memory device according to claim 1, wherein
the first layer includes silicon nitride, and
the second layer and the third layer include silicon oxynitride.

12: The semiconductor memory device according to claim 1, wherein
the first insulating layer further includes a fifth insulating layer extending between the first layer and the second layer, and between the first layer and the third layer.

13: The semiconductor memory device according to claim 12, wherein
the fifth insulating layer includes silicon oxide.

14: The semiconductor memory device according to claim 1, further comprising:
a third insulating layer extending in the first direction along the one of the semiconductor layers, wherein
a part of the third insulating layer positioned between the one of the first electrode layers and the one of the semiconductor layers acts as the charge storage portion.
